(19) United States
(12) Patent Application Publication
(10) Pub. No.: US 2007/0229159 A1
(43) Pub. Date: Oct. 4, 2007

(54) Multi-mode class-D amplifiers

(76) Inventors: Jagadeesh Krishnan, Dallas, TX (US); Paul H. Fontaine, Plano, TX (US)

Correspondence Address: TEXAS INSTRUMENTS INCORPORATED, P O BOX 655474, M/S 3999, DALLAS, TX, 75265, US

(21) Appl. No.: 11/728,883

(22) Filed: Mar. 27, 2007

Related U.S. Application Data
(60) Provisional application No. 60/788,976, filed on Apr. 4, 2006.

(51) Int. Cl. H03F 3/45

(52) U.S. Cl. 330/253

(57) ABSTRACT

Multi-mode class-D amplifiers are disclosed. An example multi-mode class-D amplifier circuit having an analog input and a digital input disclosed herein comprises a single-mode class-D amplifier having an amplifier input, a smoothing filter having a filter input and a filter output, wherein the filter output is electronically coupled to the amplifier input, and a multiplexer electronically coupled to the filter input to select between at least one of the analog input and the digital input of the multi-mode class-D amplifier circuit.

### RELATED APPLICATION

This patent claims priority from U.S. Provisional Application Ser. No. 60/788,976, entitled “Dual Mode, Low Area, Class-D Amplifier with Direct Battery Hookup” and filed on Apr. 4, 2006. U.S. Provisional Application Ser. No. 60/788,976 is hereby incorporated by reference in its entirety.

### FIELD OF THE DISCLOSURE

This disclosure relates generally to electronic amplifiers, and, more particularly, to multi-mode class-D amplifiers.

### BACKGROUND

A class-D amplifier converts an input signal to a pulse width modulation (PWM) signal that may be amplified efficiently by output stage transistors configured to operate as switches. The amplified PWM signal generated by the class-D amplifier may then be filtered to produce an amplified version of the original input signal. Class-D amplifiers are particularly suited for the amplification of audio signals due to the tolerance of audio signals to phase variations.

PWM is generated by forming a stream of pulses having widths that vary as a function of the input signal. Traditionally, generation of PWM signals involves comparing the input signal with a reference ramp signal and outputting a logical high value when the value of the input signal exceeds the value of the ramp signal and a logical low value when the value of the input signal does not exceed the value of the ramp signal. As will be readily appreciated by those having ordinary skill in the art, such an arrangement results in a pulse train, wherein the pulse widths represent the periods of time during which the input signal exceeded the ramp signal. This approach to PWM generation is called natural PWM (NPWM) in the art. More recently, digital techniques have been used to generate PWM signals from a sampled digital input signal, such as a digital pulse coded modulation (PCM) signal. These latter digital approaches to PWM generation are called uniform PWM (UPWM) in the art due to the fact that the PWM pulses are being generated at more uniform intervals corresponding to the sampling frequency of the digital input signal. In either NPWM or UPWM, the resulting output PWM signal may be viewed as a digital (as well as sampled) version of the original input signal because the output pulses correspond to sampling the input signal when the input signal exceeds the ramp signal and at a rate limited by the frequency of the ramp signal. Furthermore, the output PWM signal is digital because it has only two values, the logic high value and the logic low value. Moreover, UPWM may be viewed as a type of uniform sampling of the input signal because the output pulses may occur only at the sampling intervals of the original input signal. In contrast, NPWM may be viewed as a type of non-uniform sampling because the output pulses may occur at any time the original input signal exceeds the ramp signal and are not restricted to only particular sampling intervals in time.

In addition to differentiating a PWM signal as either NPWM or UPWM based on whether the input signal is sampled (e.g., digitized), a PWM signal is also differentiated by edge modulation and class. For example, the modulation may be single-sided or double-sided depending on the shape of the reference ramp signal. Additionally, the PWM signal may be classified as class AD or class BD depending on whether the output PWM signal varies between two or three levels, respectively.

### BRIEF DESCRIPTION OF THE DRAWINGS

FIG. 1 is a block diagram of an example prior art single-mode class-D amplifier circuit.

FIGS. 2A-2B illustrate example performance degradations associated with applying a digital input signal to the example prior art single-mode class-D amplifier circuit of FIG. 1.

FIG. 3 is a block diagram of an example multi-mode class-D amplifier capable of amplifying an analog input signal or a digital input signal.

FIG. 4 is a block diagram of a first example multi-mode class-D amplifier circuit to implement the example multi-mode class-D amplifier of FIG. 3.

FIG. 5 illustrates example total harmonic distortion performance characteristics for the first example multi-mode class-D amplifier circuit of FIG. 4 as a function of selected circuit parameters.

FIG. 6 is a block diagram of a second example multi-mode class-D amplifier circuit to implement the example multi-mode class-D amplifier of FIG. 3.

FIG. 7 is a block diagram of a pulse width modulator circuit that may be used to generate the digital input signal for the example multi-mode class-D amplifier of FIG. 3.

FIG. 8 is a block diagram of a pulse code modulator circuit that may be used to generate the digital input signal for the example multi-mode class-D amplifier of FIG. 3.

FIG. 9 is a block diagram of an example integrated audio codec based on the example multi-mode class-D amplifier of FIG. 3

FIG. 10 is a flowchart representative of an example process to implement the example multi-mode class-D amplifier of FIG. 3 and/or the example integrated audio codec of FIG. 9.

FIG. 11 is a flowchart representative of an example process to obtain the digital input signal to be processed by the example process of FIG. 10.

FIGS. 12A-12B illustrates example performance characteristics exhibited by the second example multi-mode class-D amplifier circuit 600 of FIG. 6 that may be used to implement the example multi-mode class-D amplifier of FIG. 3.

FIG. 13 is a block diagram of an example computer that may be used to implement the example processes of FIGS. 10 and/or 11 to implement the example multi-mode class-D amplifier of FIG. 3 and/or the example integrated audio codec of FIG. 9.

### DETAILED DESCRIPTION

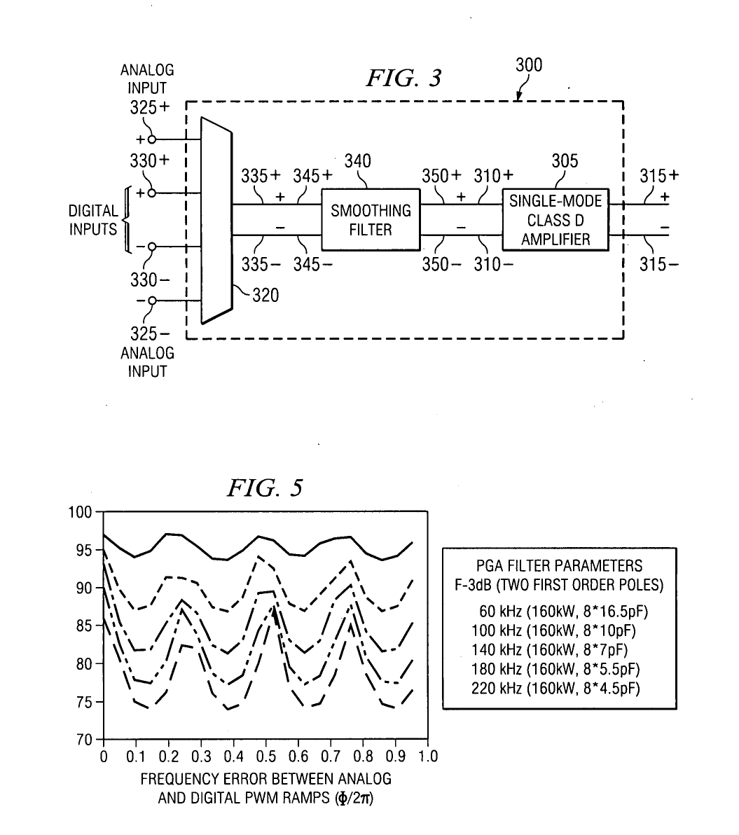

A multi-mode class-D amplifier as disclosed herein (e.g., such as the multi-mode class-D amplifier 300 of FIG. 3) is capable of amplifying one or more analog inputs and one or more digital inputs, wherein a particular one of the analog inputs or one of the digital inputs is selected for amplification. An example analog input signal may correspond to, for example, a differential analog input signal. An example digital input signal may correspond to, for example, a differential natural pulse width modulated (NPWM) input signal, a differential uniform pulse width modulated (UPWM) input signal, pulse code modulated (PCM) input symbols, etc. The resulting amplified signal may be applied to a single-ended load or a bridge-tied load.

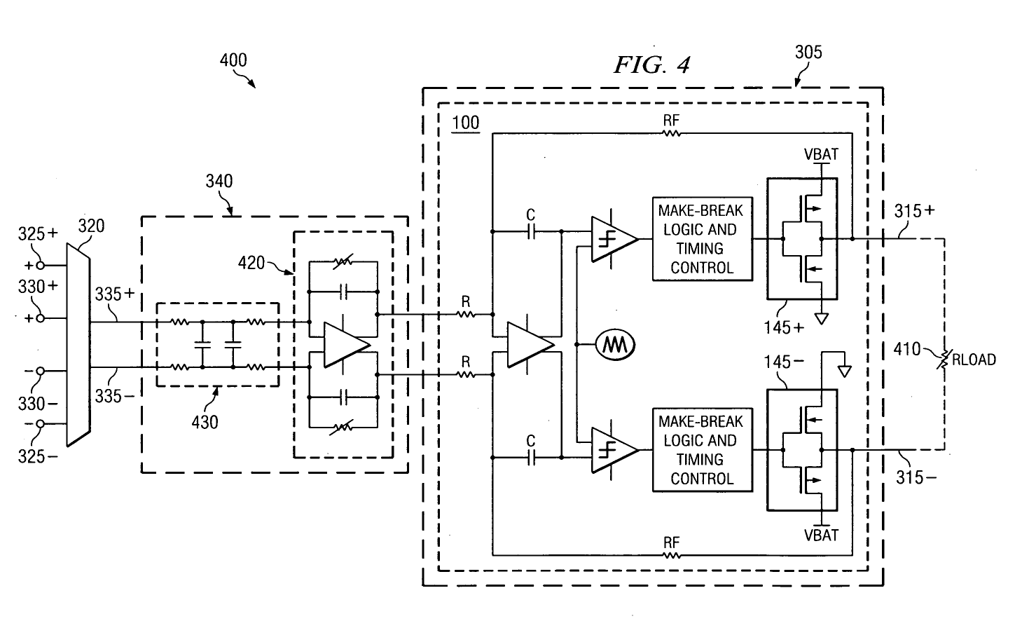

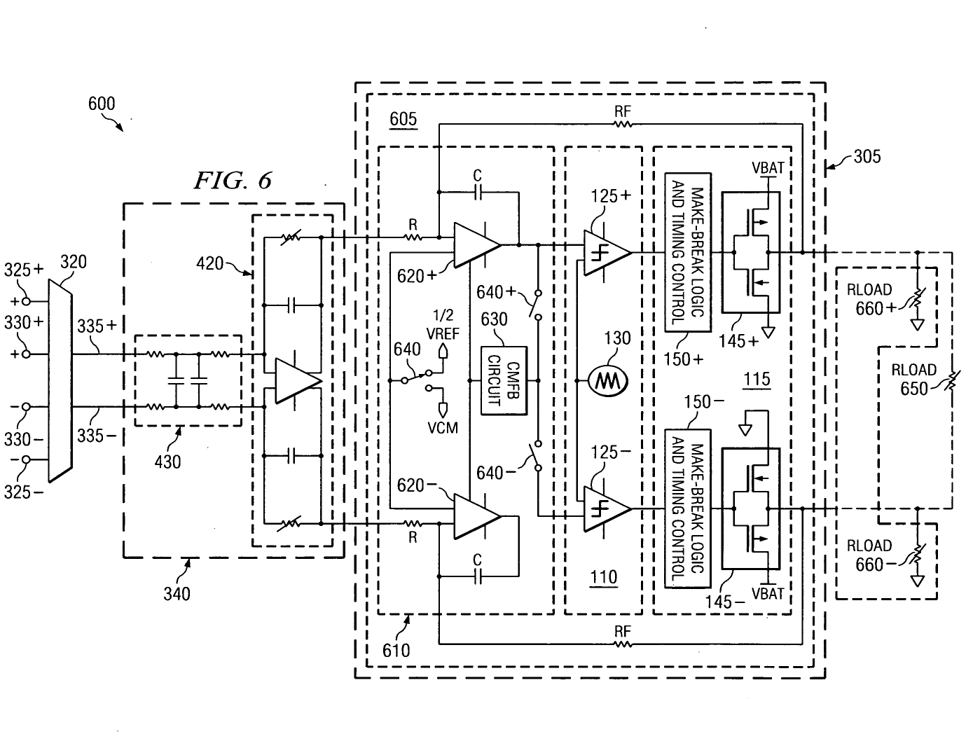

An example multi-mode class-D amplifier circuit (e.g., such as the example circuits 400 and/or 600 of FIGS. 4 and 6, respectively) to implement the multi-mode class-D amplifier disclosed herein has an analog circuit input and a digital circuit input. The example multi-mode class-D amplifier circuit is based on a single-mode class-D amplifier capable of amplifying an analog signal, a smoothing filter coupled to the single-mode class-D amplifier, and a multiplexer coupled to the filter to select between the analog circuit input and the digital circuit input of the multi-mode class-D amplifier circuit. Additionally, the example multi-mode class-D amplifier circuit may include a configuration input used to configure the single-mode class-D amplifier to support either a single-ended load or a bridge-tied load. The example multi-mode class-D amplifier circuit may also be implemented to support direct battery hookup to improve power consumption and the quality of the amplified signal.

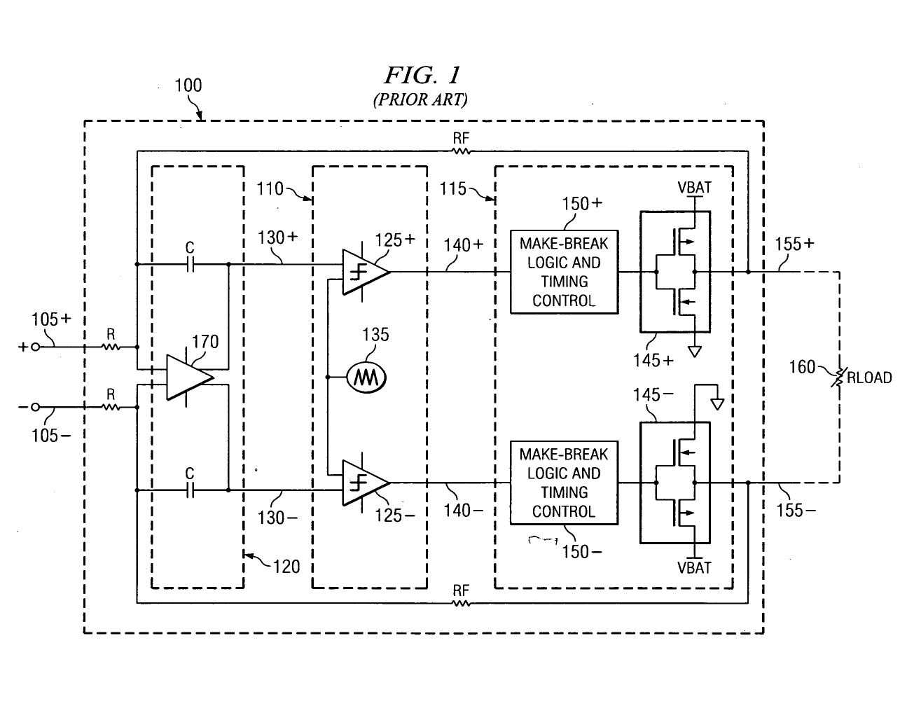

To provide a foundation to better understand the operation of the multi-mode class-D amplifiers disclosed herein, a block diagram of an example, prior art, single-mode class-D amplifier circuit 100 is shown in FIG. 1. The example prior art single-mode class-D amplifier circuit 100 is configured to operate on analog differential inputs 105+, 105− and includes a PWM generator 110, an output stage 115 and a feedback integration stage 120. The PWM generator 110 implements differential NPWM generation and includes comparators 125+, 125− to compare the PWM generator differential inputs 130+, 130− with an output of a ramp generator 135 to generate the PWM generator differential outputs 140+, 140−. The PWM generator differential outputs 140+, 140− are coupled to the output stage 115 for amplification. The output stage 115 includes power FET arrays 145+, 145− that are controlled by make-break logic and timing control circuits 150+, 150− such that the power FET arrays 145+, 145− operate in either a completely switched ON state or a completely switched OFF state. The FET arrays 145+, 145− are switched ON or OFF according to whether a pulse is present or absent, respectively, on the PWM generator differential outputs 140+, 140−. Furthermore, the FET arrays 145+, 145− are directly coupled to the battery voltage (VBAT) and, thus, the prior art single-mode class-D amplifier circuit 100 supports direct battery hookup. The FET array outputs form the differential outputs 155+, 155− of the example the prior art single-mode class-D amplifier circuit 100 and may be coupled to a load 160 in a bridge-tied load (BTL) configuration as shown in FIG. 1.

The differential outputs 155+, 155− are also fed back as inputs to the integration stage 120. The integration stage 120 includes an integration amplifier 170 to implement a first-order feedback loop having a bandwidth that suppresses non-linear distortions caused by switching of the FET arrays 145+, 145− and/or operation of the ramp generator 135, and/or that suppresses noise and ripple from the power supply driving the example prior art class-D amplifier circuit 100. As is known from delta-sigma converter theory, employing an integrator before a noise adding element and then feeding back the inverse of the circuit output to the input of the integrator pushes the noise effects higher up in the frequency band. In the case of audio signals applied to the analog differential inputs 105+, 105−, an external low pass filter may be used to filter out the noise effects and extract the amplified audio signal. In much the same manner, the feedback loop implemented using the integration stage 120 thereby improves the total harmonic distortion (THD) and power supply rejection ratio (PSRR) associated with the prior art class-D amplifier circuit 100. Additionally, the ramp generator 135 may be configured to generate a ramp signal whose amplitude is proportional to the power supply voltage (e.g., shown as VBAT in FIG. 1). Such a configuration further improves the PSRR performance of the prior art class-D amplifier circuit 100 because the overall gain of the ramp signal relative to the power supply is constant and independent of any variations in the power supply voltage.

An example implementation of the prior art class-D amplifier circuit 100 is described by Forejt, et al. in “A 250 mW Class D design with battery hookup in a 90 nm process,” published in the Proceedings of the IEEE CICC 2004, which is incorporated by reference herein in its entirety. The example implementation described by Forejt, et al. further discloses in particularity how the prior art class-D amplifier circuit 100 may be configured to support direct battery hookup.

The example prior art class-D amplifier circuit 100 is well-suited for amplification of analog input signals applied to the analog differential inputs 105+, 105−. However, the prior art class-D amplifier circuit 100 is not particularly suited for amplification of digital (sampled) input signals applied to the analog differential inputs 105+, 105−, such as, for example, NPWM input signals, UPWM input signals, PCM input symbols converted to representative voltage levels and applied to the inputs 105+, 105−, etc. This is because phase and frequency mismatches between the digital carrier (or sampling frequency) associated with the digital (sampled) input signal and the analog ramp signal generated by the ramp generator 135 introduce instability, distortion and noise aliasing effects that may degrade amplifier performance. For example, frequency mismatch between the digital carrier and the analog ramp may introduce intermodulation distortion and/or noise aliasing. Additionally or alternatively, phase mismatch between the digital carrier and the analog ramp may introduce instability and/or distortion into the feedback loop due to the comparators 125+, 125− potentially activating multiple times within a pulse interval.

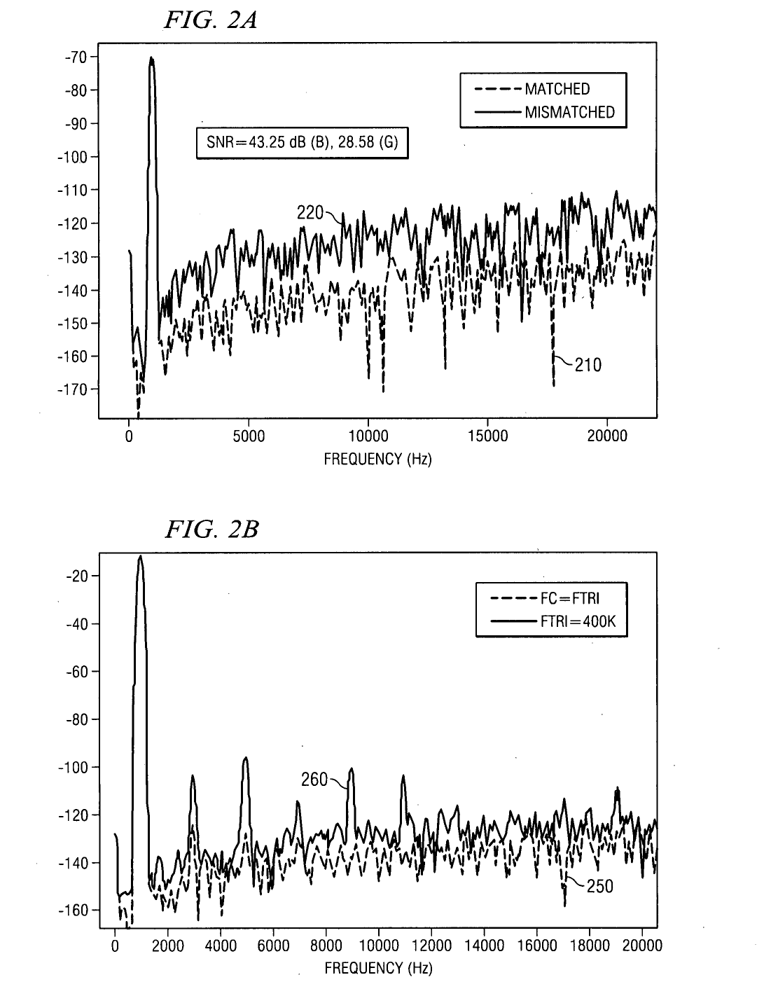

Example performance degradations for the example prior art class-D amplifier circuit 100 caused by phase and frequency mismatches between the digital carrier (or sampling frequency) associated with the digital (sampled) input signal and the analog ramp signal generated by the ramp generator 135 are shown in FIGS. 2A-2B. FIG. 2A illustrates the effect of frequency and phase mismatch on signal-to-noise ratio (SNR) and depicts two example performance curves 210 and 220. The two performance curves illustrate the output power of the prior art class-D amplifier circuit 100 as a function of frequency for a digital PWM input signal corresponding to a low-power 1 kHz sinusoidal signal and in which the digital carrier and analog ramp frequencies are nominally 400 kHz. Performance curve 210 corresponds to the ideal scenario in which the digital carrier and the analog ramp are perfectly matched and depicts an output SNR of 43.25 dB, computed as the ratio of the output power at 1 kHz to the output power at all other frequencies. In contrast, performance curve 220 illustrates the degradation in SNR performance corresponding to a phase and frequency mismatch of 20 kHz between the digital carrier associated with the digital PWM input signal and the analog ramp of the prior art class-D amplifier circuit 100. This mismatch results in an output SNR of 28.58 dB, illustrating that the phase and frequency mismatch causes an SNR degradation of 14.67 dB.

Similarly, FIG. 2B illustrates the effect of frequency and phase mismatch on total harmonic distortion (THD) and depicts two example performance curves 250 and 260. The two THD performance curves 250 and 260 illustrate the output power of the prior art class-D amplifier circuit 100 as a function of frequency for a digital PWM input signal corresponding to a high-power 1 kHz sinusoidal signal and in which the digital carrier and analog ramp frequencies are nominally 400 kHz. Performance curve 250 illustrates THD corresponding to the ideal scenario in which the digital carrier associated with the digital PWM input signal and the analog ramp of the prior art class-D amplifier circuit 100 are aligned. In contrast, performance curve 260 illustrates the degradation in THD corresponding to a phase and frequency mismatch of 20 kHz between the digital carrier and analog ramp. The degradation in THD performance is exhibited as an increase in output power at harmonics of the PWM digital input signal as shown in performance curve 260 relative to the ideal case illustrated by performance curve 250.

FIGS. 2A-2B illustrate that phase and frequency mismatches between the digital carrier (or sampling clock signal) associated with the digital (sampled) input signal and the analog ramp signal generated by the ramp generator 135 can cause significant performance degradation. A phase locked loop (PLL) or delay locked loop (DLL) could be incorporated into the example prior art class-D amplifier circuit 100 to match the frequencies and phases of the digital carrier and the analog ramp. However, such a solution may be undesirable because it could result in a significant increase in the area of the circuit implementation.

A block diagram of an example multi-mode class-D amplifier 300 capable of amplifying both analog and digital input signals is illustrated in FIG. 3. The multi-mode class-D amplifier 300 includes a single-mode class-D amplifier 305 having differential analog inputs 310+, 310− and differential outputs 315+, 315−. The differential outputs 315+, 315− form the differential circuit outputs of the multi-mode class-D amplifier 300. The single-mode class-D amplifier 305 could be implemented, for example, by the example prior art single-mode class-D amplifier circuit 100 of FIG. 1 (as shown in FIG. 4 discussed below), by the circuit illustrated in FIG. 6 and discussed below, and/or any other single-mode class-D amplifier architecture. The multi-mode class-D amplifier 300 also includes a multiplexer 320 that selects between differential analog circuit inputs 325+, 325− and differential digital circuit inputs 330+, 330−, and then routes the selected inputs to the differential multiplexer output 335+, 335− for subsequent amplification. Although the example of FIG. 3 depicts the multi-mode class-D amplifier 300 as having one differential analog circuit input pair 325+, 325− and one differential digital circuit input pair 330+, 330−, persons of ordinary skill in the art will appreciate that the multiplexer 320 could be implemented to support any number of differential analog circuit input pairs 325+, 325− and any number of differential digital circuit input pairs 330+, 330−.

As discussed above in connection with FIGS. 2A-2B, application of digital (sampled) signals from differential digital circuit inputs 330+, 330− directly to the single-mode class-D amplifier 305 could result in significant performance degradation due to frequency and/or phase mismatches between the digital carrier (sampling clock signal) associated with the digital input signal and the ramp signal generated by the ramp generator internal to the single-mode class-D amplifier 305. To mitigate the degradation in the performance of the single-mode class-D amplifier 305 that could occur if digital (sampled) signals were applied directly from the differential digital circuit inputs 330+, 330− to the differential analog inputs 310+, 310, the multi-mode class-D amplifier 300 further includes a smoothing filter 340 having differential filter inputs 345+, 345− and differential filter outputs 350+, 350−. The smoothing filter 340 is coupled between the multiplexer 320 and the single-mode class-D amplifier 305 as shown FIG. 3.

Generally, the smoothing filter 340 is implemented as a low pass filter having a bandwidth chosen such that the smoothing filter 340 has little to no effect on analog signals routed from the differential analog circuit inputs 325+, 325− to the smoothing filter 340 via the multiplexer 320. However, the bandwidth of the low pass filter implementing the smoothing filter 340 should also be chosen to suppress the digital carrier and/or higher frequency sampling harmonics associated with digital (sampled) signals routed from the differential digital circuit inputs 330+, 330− to the smoothing filter 340 via the multiplexer 320. By suppressing the digital carrier and/or higher frequency sampling harmonics associated with the digital (sampled) signals applied to the differential digital circuit inputs 330+, 330−, the single-mode class-D amplifier 305 sees an essentially analog signal at its differential analog inputs 310+, 310. Therefore, because the single-mode class-D amplifier 305 always operates on a substantially analog signal whether the signal is provided by an analog signal applied to the differential analog circuit inputs 325+, 325− or a digital signal applied to the differential digital circuit inputs 330+, 330−, the multi-mode class-D amplifier 300 is made substantially immune to phase and/or frequency mismatch effects associated with amplification of digital input signals.

A first example circuit 400 to implement the example multi-mode class-D amplifier 300 of FIG. 3 is shown in FIG. 4. As described above, the first example multi-mode class-D amplifier circuit 400 implements the input stage of the multi-mode class-D amplifier 300 using the multiplexer 320 to select between differential analog circuit inputs 325+, 325− and differential digital circuit inputs 330+, 330−. The multiplexer 320 routes the selected inputs to the differential multiplexer output 335+, 335− for subsequent amplification. Additionally, to implement the single-mode class-D amplifier 305 included in the example multi-mode class-D amplifier 300, the example multi-mode class-D amplifier circuit 400 may utilize the prior art class-D amplifier circuit 100 of FIG. 1, as shown in FIG. 4. Of course, other amplifier arrangements may be used. According to the example of FIG. 4, the FET arrays 145+, 145− are directly coupled to the battery voltage (VBAT) and, thus, the example mode class-D amplifier circuit 400 supports direct battery hookup. In other configurations, the FET arrays 145+, 145− may not be coupled directly to the battery. Furthermore, the differential circuit outputs 315+, 315− of the example mode class-D amplifier circuit 400 may be coupled to the load 410 in a BTL configuration as shown.

In the example multi-mode class-D amplifier circuit 400, the smoothing filter 340 is implemented using a programmable gain amplifier (PGA) 420 and a passive network implementing a two-pole low-pass input filter 430 at the differential inputs to the PGA 420. The PGA 420 is chosen to implement the smoothing filter 340 in the example multi-mode class-D amplifier circuit 400 because most systems employing a class-D amplifier will also employ a PGA to provide the flexibility of having different amplifier gain settings. For example, a traditional receive audio codec includes a PCM coder followed by a sigma-delta (ΣΔ) digital-to-analog (D/A) converter, a PGA and an output driver, such as an analog, single-mode class-D amplifier. If the example multi-mode class-D amplifier 300 is used to replace the single-mode class-D amplifier in the receive audio codec, the PGA would already be present in the system and preceding the mode class-D amplifier 300. Of course, any type of amplifier could be used instead of the PGA 420 to implement the smoothing filter 340 in the example multi-mode class-D amplifier circuit 400.

In the example of FIG. 4, the two-pole low-pass input filter 430 is configured to pass analog signals applied to the differential analog circuit inputs 325+, 325− and yet filter the digital carrier frequency and/or sampling harmonics associated with digital signals applied to the differential digital circuit inputs 330+, 330−. For example, if an externally generated PWM signal having a digital carrier frequency of 400 kHz is expected to be applied to the differential digital circuit inputs 330+, 330−, then the passive elements of the two-pole low-pass input filter 430 should be selected to suppress the 400 kHz carrier and harmonics. FIG. 5 illustrates the effects of passive element selection on THD for such a digital input PWM signal.

Turning to FIG. 5, the performance curves depicted therein illustrate the effect of the two-pole low-pass input filter 430 on the THD exhibited by the example multi-mode class-D amplifier circuit 400. As shown, each performance curve depicts THD performance for a particular selection of passive elements resulting in a particular bandwidth for the two-pole low-pass input filter 430. The performance curves of FIG. 5 indicate that THD performance improves as the bandwidth of the two-pole low-pass input filter 430 is decreased. However, reduction of the filter bandwidth limits the bandwidth of signals that can be applied to the differential analog circuit inputs 325+, 325− and/or the differential digital circuit inputs 330+, 330− of the multi-mode class-D amplifier circuit 400. Thus, persons having ordinary skill in the art will appreciate that the passive elements of the two-pole low-pass input filter 430 should be selected to tune the filter bandwidth to achieve a compromise between the expected bandwidth of the input signals to be applied to the multi-mode class-D amplifier circuit 400 and the expected resulting THD performance (e.g., via analyzing a set of performance curves such as those shown in FIG. 5).

Returning to FIG. 4, the smoothing filter 340 implemented via the PGA 420 and the two-pole low-pass input filter 430 reduces the performance degradations associated with phase and/or frequency mismatch between the digital carrier frequency associated with the digital signal applied to the differential digital circuit inputs 330+, 330− and the analog ramp generated within the single-mode class-D amplifier 305. The smoothing filter 340 operates to smooth any input digital signal such that the single-mode class-D amplifier 305 sees an analog-like signal at its inputs regardless of whether and analog signal or digital signal is being amplified by the multi-mode class-D amplifier circuit 400. Furthermore, from an implementation perspective, the additional overhead of the smoothing filter 340 implemented via the PGA 420 and the two-pole low-pass input filter 430 is minimal. As mentioned previously, the PGA 420 will likely already be present in many applications. Thus, the addition of the passive elements forming the two-pole low-pass input filter 430 will typically have negligible impact on the size and/or power consumption of a stand-alone implementation of the multi-mode class-D amplifier circuit 400 or an integrated solution employing the multi-mode class-D amplifier circuit 400.

As shown in FIG. 4, the first example multi-mode class-D amplifier circuit 400 is configured to support only BTL output configurations. A second example circuit 600 to implement the example multi-mode class-D amplifier 300 of FIG. 3 that is capable of supporting both BTL and single-ended load (SEL) output configurations is shown in FIG. 6. The second example multi-mode class-D amplifier circuit 600 also includes the multiplexer 320 to select between the differential analog circuit inputs 325+, 325− and the differential digital circuit inputs 330+, 330−. The multiplexer 320 routes the selected inputs to the differential multiplexer output 335+, 335− for subsequent amplification. Additionally, the second example multi-mode class-D amplifier circuit 600 also includes the smoothing filter 340 implemented via the PGA 420 and the two-pole low-pass input filter 430, as in the case of the first example multi-mode class-D amplifier circuit 400 of FIG. 4. However, as compared to the first example multi-mode class-D amplifier circuit 400, the second example multi-mode class-D amplifier circuit 600 of FIG. 6 utilizes a different circuit 605 to implement the single-mode class-D amplifier 305 that supports both BTL and SEL output configurations.

The single-mode class-D amplifier circuit 605 in the second example multi-mode class-D amplifier circuit 600 shares some similarities with the example single-mode class-D amplifier circuit 100 of FIG. 1 (and which is used to implement the first example multi-mode class-D amplifier circuit 400 of FIG. 4). As such, like components in FIGS. 1 and 6 are labeled with the same reference numerals. In particular, the single-mode class-D amplifier circuit 605 of FIG. 6 includes the PWG generator 110 and the output stage 115 as implemented in the single-mode class-D amplifier circuit 100 of FIG. 1. Thus, the FET arrays 145+, 145− are directly coupled to the battery voltage (VBAT) and, thus, the second example mode class-D amplifier circuit 600 supports direct battery hookup. However, while the single-mode class-D amplifier circuit 100 of FIG. 1 utilizes only a single differential integration amplifier 170 in its integration stage 120, the integration stage 610 of the single-mode class-D amplifier circuit 605 of FIG. 6 utilizes two differential integration amplifiers 620+ and 620−, a common-mode feedback circuit 630 and switches 640, 640+ and 640−.

Examining the integration stage 610 of the single-mode class-D amplifier circuit 605 in greater detail, when switches 640+, 640− are closed and switch 640 is coupled to the common-mode reference voltage (VCM), the integration amplifiers 620+, 620− implement a fully differential feedback loop via any known implementation of the common-mode feedback circuit 630. In this configuration, the second example multi-mode class-D amplifier circuit 600 supports a BTL output configuration and can drive, for example, the bridge-tied load 650 as shown. As a result of the differential bridge coupling in this configuration, the second example multi-mode class-D amplifier circuit 600 will, therefore, output PWM signals having three levels (e.g., BD-mode PWM).

Conversely, when the switches 640+, 640− are open and the switch 640 is coupled to one-half the reference voltage (½ VREF), the common-mode feedback circuit 630 is bypassed and the integration amplifiers 620+, 620− implement two single-ended feedback loops. In this configuration, the second example multi-mode class-D amplifier circuit 600 supports an SEL output configuration and can drive, for example, the two single-ended loads 660+, 660− as shown. As a result of the single-ended coupling in this configuration, the second example multi-mode class-D amplifier circuit 600 will, therefore, output PWM signals having two levels (e.g., AD-mode PWM).

Thus, the second example multi-mode class-D amplifier circuit 600 implements a flexible multi-mode class-D amplifier capable of amplifying analog or digital input signals and driving bridge-tied loads or single-ended loads. Additionally, due to the smoothing filter 340, the second example multi-mode class-D amplifier circuit 600 is substantially immune to phase and/or frequency mismatches between the digital carrier frequency and/or sample harmonics associated with the differential digital circuit inputs 330+, 330− and the analog ramp generator 130. Furthermore, persons having ordinary skill in the art will appreciate that the second example multi-mode class-D amplifier circuit 600 can be implemented in an efficient footprint in either a stand-alone integrated circuit package or in an integrated solution supporting additional functionality.

Again, as noted above, various different amplifier circuits and/or configurations may be used in conjunction with the concepts disclosed herein. Thus, although two example circuit configurations are provided herein, the two example circuit configurations are not the only ways to implement such circuits.

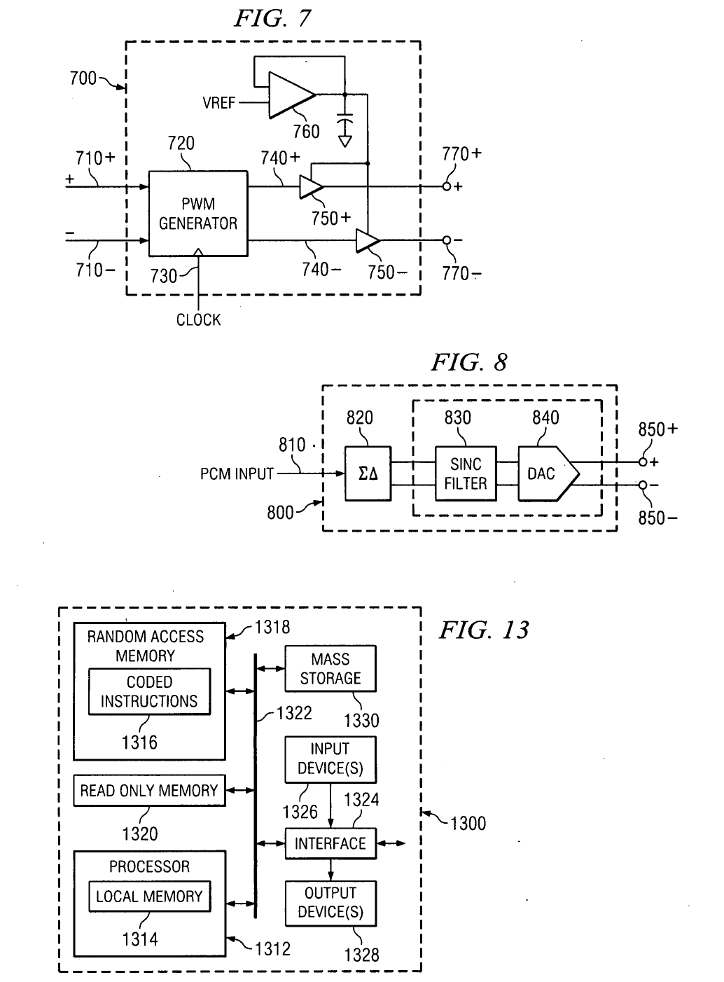

An example PWM circuit 700 that can be used to generate a digital signal to be applied to the differential digital circuit inputs 330+, 330− of the multi-mode class-D amplifier 300 of FIG. 3 and/or the example multi-mode class-D amplifier circuits 400 and/or 600 of FIGS. 4 and 6, respectively, is shown in FIG. 7. The PWM circuit 700 accepts a differential analog signal at the differential PWM generator inputs 710+, 710− of a PWM generator 720. The PWM generator 720 may be, for example, any known PWM generator, such as a UPWM generator operated at a clock rate based on the input clock signal 730. The differential PWM generator outputs 740+, 740− of the PWM generator 720 are amplified via the output amplifiers 750+, 750− and biased via the bias amplifier 760 as shown. The resulting outputs of the output amplifiers 750+, 750− form the differential digital PWM circuit outputs 770+, 770− that may be applied to the differential digital circuit inputs 330+, 330− of the multi-mode class-D amplifier 300 and/or the example multi-mode class-D amplifier circuits 400 and/or 600.

Another technique or approach for generating digital signals is shown in FIG. 8. FIG. 8 depicts an example pulse code modulator circuit 800 that can be used to generate a digital signal to be applied to the differential digital circuit inputs 330+, 330− of the multi-mode class-D amplifier 300 of FIG. 3 and/or the example multi-mode class-D amplifier circuits 400 and/or 600 of FIGS. 4 and 6, respectively. The example pulse code modulator circuit 800 accepts a stream of PCM codewords at its PCM input 810 and applies the input PCM stream to a sigma-delta (ΣΔ) modulator 820. The ΣΔ modulator 820 converts the input PCM stream to multi-level differential output signals that vary at the sampling rate of the input PCM stream. The outputs of the ΣΔ modulator 820 are applied to a sinc filter 830 to reduce the quantization noise from the ΣΔ modulator 820 as is known in the art. The outputs of the sinc filter 830 are applied to a known D/A converter 840 to generate differential digital voltage outputs that vary at the sampling rate of the input PCM stream. The resulting outputs of the D/A converter 840 form the differential digital pulse-coded modulator circuit outputs 850+, 850− that may be applied to the differential digital circuit inputs 330+, 330− of the multi-mode class-D amplifier 300 and/or the example multi-mode class-D amplifier circuits 400 and/or 600.

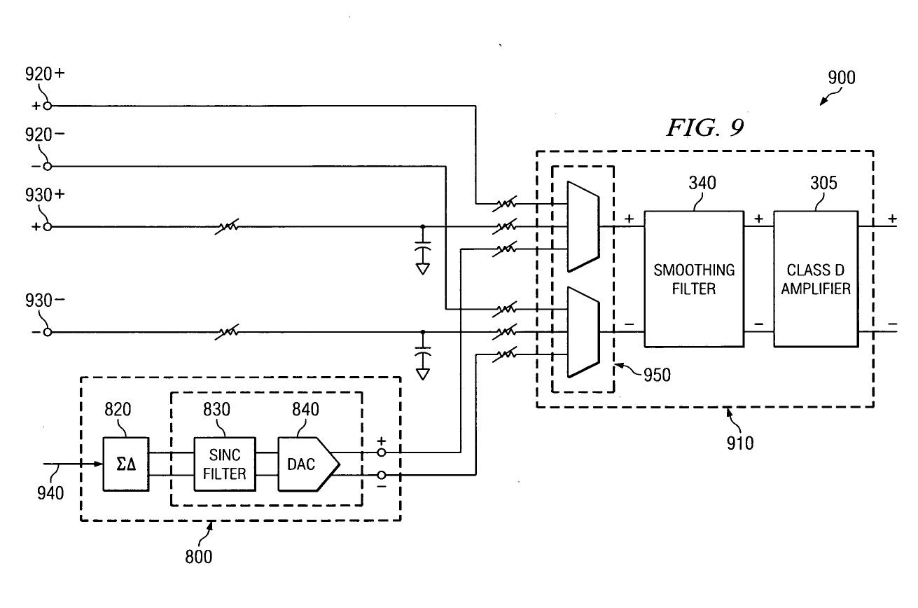

To provide an example of an integrated solution employing a multi-mode class-D amplifier as disclosed herein, an example integrated receive audio codec 900 based on a multi-mode class-D amplifier 910 is shown in FIG. 9. The example integrated receive audio codec 900 is capable of amplifying input signals applied to the differential analog circuit inputs 920+, 920−, the differential PWM digital circuit inputs 930+0.930− or the PCM digital circuit input 940. The multi-mode class-D amplifier 910 implemented in the integrated receive audio codec 900 is similar to the multi-mode class-D amplifier 300 of FIG. 3 and includes the single-mode class-D amplifier 305 and the smoothing filter 340 discussed above. For example, the single-mode class-D amplifier 305 in the integrated receive audio codec 900 could be implemented by the example prior art single-mode class-D amplifier circuit 100 of FIG. 1. Alternatively, the single-mode class-D amplifier 305 in the integrated receive audio codec 900 could be implemented by the single-mode class-D amplifier circuit 605 of FIG. 6, thereby providing support for both SEL and BTL output configurations. Additionally, the smoothing filter 340 could be implemented using the PGA 420 and the two-pole low-pass input filter 430 of FIG. 4.

However, unlike the two-input multiplexer 320 used in the multi-mode class-D amplifier 300 of FIG. 3, the multi-mode class-D amplifier 910 used to implement the integrated receive audio codec 900 of FIG. 9 includes a three-input multiplexer 950 to select among the input signals applied to the differential analog circuit inputs 920+, 920−, the differential PWM digital circuit inputs 930+0.930− and the PCM digital circuit input 940. Thus, the integrated receive audio codec 900 may be configured to amplify a differential analog (e.g., audio) signal applied to the differential analog circuit inputs 920+, 920−. Alternatively, the integrated receive audio codec 900 may be configured to amplify a differential PWM digital signal applied to the differential PWM digital circuit inputs 930+, 930−. For example, such a differential PWM digital signal may be generated by the PWM circuit 700 of FIG. 7. The PWM circuit 700 could be implemented external to the integrated receive audio codec 900 as indicated in FIG. 9, or integrated into the receive audio codec 900 (not shown).

As yet another alternative, the integrated receive audio codec 900 may be configured to amplify a PCM digital signal applied to the PCM digital circuit input 940. To support amplification of PCM digital signals, the integrated receive audio codec 900 includes the pulse code modulator circuit 800 of FIG. 8 to convert the input PCM digital signal applied to the PCM digital circuit input 940 to a differential digital signal that can be processed by the multi-mode class-D amplifier 910. Preferably, the sinc filter 830 should be implemented in the integrated receive audio codec 900 such that the notch of the sinc filter coincides with the ramp frequency of the ramp generator used to implement the multi-mode class-D amplifier 910.

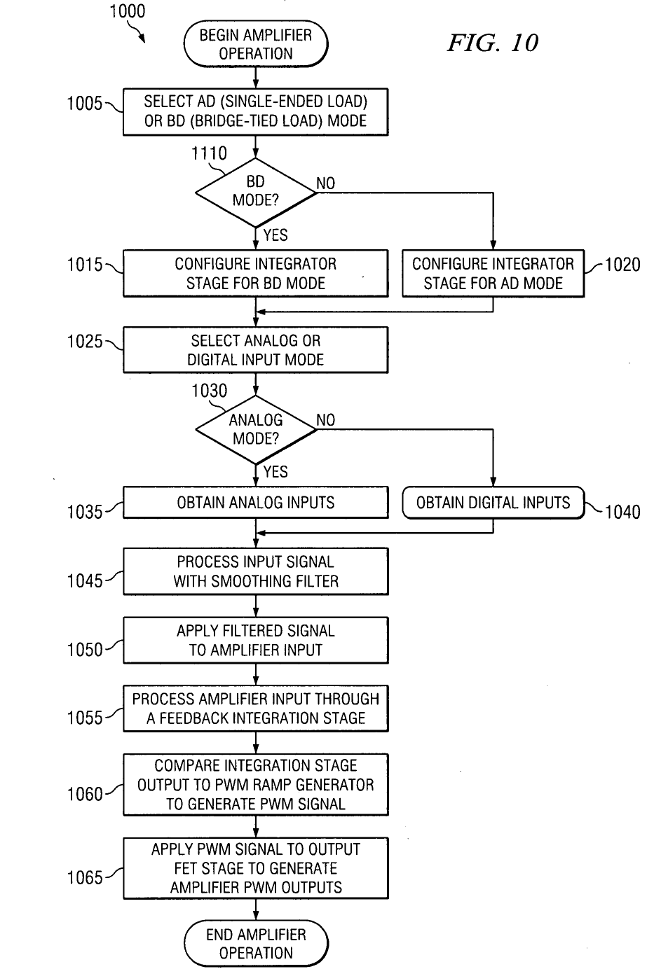

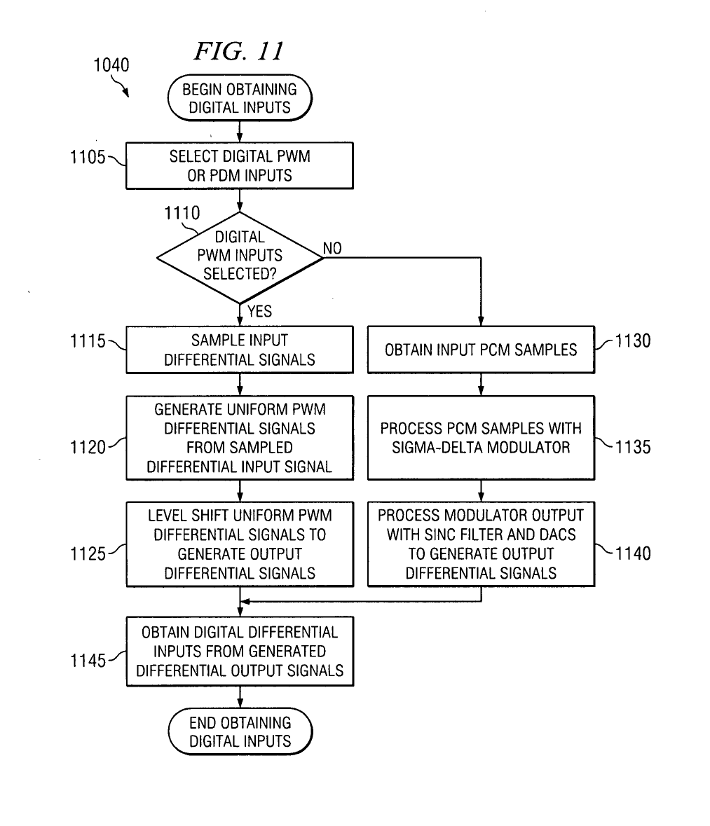

Flowcharts representative of example processes that may be executed to implement the multi-mode class-D amplifier 300 of FIG. 3 and/or the example integrated receive audio codec 900 of FIG. 9 are shown in FIGS. 10-11. In these examples, the processes represented by each flowchart may be implemented by one or more instructions, one or more sets of instructions, or one or more programs for execution by: (a) a processor, such as the processor 1312 shown in the example computer 1300 discussed below in connection with FIG. 13, (b) a controller, and/or (c) any other suitable device. The one or more instructions, one or more sets of instructions, or one or more programs may be embodied in software or firmware stored on a tangible medium such as, for example, a flash memory, a CD-ROM, a floppy disk, a hard drive, a DVD, or a memory associated with the processor 1312, but persons of ordinary skill in the art will readily appreciate that any or all of the instructions, the sets of instructions, or the entire program or programs and/or portions thereof could alternatively be executed by a device other than the processor 1312 and/or embodied in firmware or dedicated hardware in a well-known manner (e.g., implemented by an application specific integrated circuit (ASIC), a programmable logic device (PLD), a field programmable logic device (FPLD), discrete logic, etc.). For example, any or all of the multi-mode class-D amplifier 300 and/or the example integrated receive audio codec 900 could be implemented by any combination of software, hardware, and/or firmware. Also, some or all of the processes represented by the flowchart of FIGS. 10-11 may be implemented manually. Further, although the example processes are described with reference to the flowcharts illustrated in FIGS. 10-11, persons of ordinary skill in the art will readily appreciate that many other techniques for implementing the example methods and apparatus described herein may alternatively be used. For example, with reference to the flowcharts illustrated in FIGS. 10-11, the order of execution of the blocks may be changed, and/or some of the blocks described may be changed, eliminated, combined and/or subdivided into multiple blocks.

An example process 1000 that may be executed to implement the multi-mode class-D amplifier 300 of FIG. 3 and/or the example integrated receive audio codec 900 of FIG. 9 are illustrated in FIG. 10. In the following, operation of the example process 1000 is described with reference to the second example multi-mode class-D amplifier circuit 600 of FIG. 6 and/or the example integrated receive audio codec 900 as appropriate. With this in mind, and referring to FIG. 6, the example process 1000 of FIG. 10 begins execution at block 1005 at which the multi-mode class-D amplifier circuit 600 is configured to operate in either AD mode or BD mode. As discussed above, AD mode corresponds to two-level PWM signal generation and is associated with an SEL output configuration, whereas BD mode corresponds to three-level PWM signal generation and is associated with a BTL output configuration. At block 1005, configuration of AD mode or BD mode may be achieved through, for example, an input pin (not shown) coupled to switches 640, 640+ and 640−.

If BD mode is selected (block 1010), control proceeds to block 1015 at which the integration stage 610 of the multi-mode class-D amplifier circuit 600 is configured to operate in BD mode and, thus, support a BTL output configuration. For example, at block 1015, switches 640+, 640− are closed and switch 640 is coupled to the common-mode reference voltage (VCM), thereby causing the integration amplifiers 620+, 620− to implement a fully differential feedback loop. In this configuration, the multi-mode class-D amplifier circuit 600 supports a BTL output configuration and can drive, for example, the bridge-tied load 650 as shown in FIG. 6. If, however, BD mode is not selected (block 1010), control proceeds to block 1020 at which the integration stage 610 of the second example multi-mode class-D amplifier circuit 600 is configured to operate in AD mode and, thus, support an SEL output configuration. For example, at block 1020, switches 640+, 640− are opened and switch 640 is coupled to one-half the reference voltage (½ VREF), causing the integration amplifiers 620+, 620− to implement two single-ended feedback loops. In this configuration, the multi-mode class-D amplifier circuit 600 supports an SEL output configuration and can drive, for example, the two single-ended loads 660+, 660− as shown in FIG. 6.

After the integration stage 610 of the second example multi-mode class-D amplifier circuit 600 is configured at blocks 1015 or 1020, control proceeds to block 1025 at which the multi-mode class-D amplifier circuit 600 is configured to operate in either analog or digital input mode. For example, at block 1025, configuration of either analog or digital input mode may be achieved by selection pin(s) (not shown) coupled to the multiplexer 320 (or the multiplexer 950 of FIG. 9 in the case of an integrated receive audio codec implementation). If analog input mode is selected (block 1030), control proceeds to block 1035 at which an analog input signal is selected for amplification. For example, if block 1035 implements the stand-alone multi-mode class-D amplifier 600, then at block 1035 the multiplexer 320 selects the differential analog circuit inputs 325+, 325− to obtain the analog input signal for processing. Alternatively, if block 1035 implements the integrated receive audio codec 900 of FIG. 9, then at block 1035 the multiplexer 950 selects the differential analog circuit inputs 920+, 920− to obtain the analog input signal for processing.

If, however, analog input mode is not selected (block 1030), then digital input mode has been selected and control proceeds to block 1040 at which a digital input signal is selected for amplification. For example, if block 1040 implements the stand-alone multi-mode class-D amplifier 600, then at block 1040 the multiplexer 320 selects the differential digital circuit inputs 330+, 330− to obtain the digital input signal for processing. Alternatively, if block 1040 implements the integrated receive audio codec 900 of FIG. 9, an example process for implementing the processing at block 1040 is shown in FIG. 11. In any case, after the input mode is selected and the appropriate input signal is obtained at blocks 1035 or 1040, control proceeds to block 1045.

At block 1045, the selected input signal is processed by the smoothing filter 340. The smoothing filter 340 may be implemented, for example, via the PGA 420 and the two-pole low-pass input filter 430. The two-pole low-pass input filter 430 is configured to pass analog input signals substantially unaltered, whereas digital input signals are filtered to reduce the performance degradations associated with phase and/or frequency mismatch between the digital carrier frequency associated with the input digital signal and the analog ramp frequency associated with the analog ramp generator used by the multi-mode class-D amplifier 600 to generate its differential output PWM signals.

Next, at block 1050, the differential outputs of the smoothing filter 340 are applied to the differential inputs of the single-mode class-D amplifier circuit 605 used to implement the multi-mode class-D amplifier circuit 600 as shown in FIG. 6. Then, at block 1055, the single-mode class-D amplifier differential inputs are processed by the integration stage 610 which implements a feedback loop to, for example, suppress non-linear distortion and noise within the multi-mode class-D amplifier circuit 600. Control then proceeds to block 1060 at which the differential outputs of the integration stage 610 and to the ramp signal generated by the ramp generator 135 are compared via comparators 125+, 125− to generate differential PWM signals corresponding to the input signal selected at block 1025. Next, control proceeds to block 1065 at which the differential PWM signals generated by the comparators 125+, 125− are amplified via the FET arrays 145+, 145− included in the output stage 115 of the multi-mode class-D amplifier circuit 600. The amplified differential PWM signals then form the differential PWM circuit outputs to be coupled to a single-ended load or a bridge-tied load as selected at block 1005. Execution of the example process 1000 then ends.

An example process 1040 that may be executed to implement block 1040 of the example process 1000 of FIG. 10 is illustrated in FIG. 11. The example process 1040 operates to select either an input digital PWM signal or an input PCM digital signal when digital input mode is selected at block 1030 of FIG. 10 in the case of the process 1000 implementing the example integrated received audio codec 900 of FIG. 9. Referring also to FIG. 9, the example process 1040 of FIG. 11 begin execution at block 1105 at which the integrated received audio codec 900 is configured to process either its differential PWM digital circuit inputs 930+0.930− or its PCM digital circuit input 940. For example, at block 1105, selection of either the differential PWM digital circuit inputs 930+0.930− or the PCM digital circuit input 940 may be achieved by selection pin(s) (not shown) coupled to the multiplexer 950.

If the differential PWM digital circuit inputs 930+0.930− are selected for processing (block 1110), digital PWM signals that are applied to the differential PWM digital circuit inputs 930+0.930− will be amplified by the integrated receive audio codec 900. The digital PWM signals applied to the differential PWM digital circuit inputs 930+0.930− may be generated by, for example, PWM circuit 700 of FIG. 7 which may be integrated in or external to the integrated receive audio codec 900. For example, to generate the digital PWM signals to be applied to the differential PWM digital circuit inputs 930+0.930−, control proceeds to block 1115 at which the PWM circuit 700 accepts a differential analog signal and applies it to the differential PWM generator inputs 710+, 710− of the PWM generator 720. The PWM generator 720 may be implemented, for example, as a UPWM generator and, thus, will sample the differential analog signal applied to the differential PWM generator inputs 710+, 710− using any known sampling technique (e.g., such as the well-known sample-and-hold technique). Control then proceeds to block 1120 at which the PWM generator 720 generates UPWM differential signals based on the input differential analog signal sampled at block 1115. The UPWM differential signal is output via the differential PWM generator outputs 740+, 740− of the PWM generator 720. Next, control proceeds to block 1125 at which the UPWM differential signals output from the differential PWM generator outputs 740+, 740− are level shifted and/or amplified via the bias amplifier 760 and the output amplifiers 750+, 750−, respectively. The resulting amplified and/or biased digital PWM signals are output by the differential digital PWM circuit outputs 770+, 770− and applied to the differential PWM digital circuit inputs 930+0.930− of the integrated receive audio codec 900.

If, however, the PCM digital circuit input 940 is selected for processing (block 1110), control proceeds to block 1130 at which the pulse code modulator circuit 800 included in the integrated receive audio codec 900 accepts a stream of PCM codewords at the PCM digital circuit input 940. Next, control proceeds to block 1135 at which the input PCM stream is applied to the ΣΔ modulator 820. The ΣΔ modulator 820 converts the input PCM stream to multi-level differential output signals that vary at the sampling rate of the input PCM stream. Then, at block 1140, the outputs of the ΣΔ modulator 820 are applied to a sinc filter 830 to reduce the quantization noise from the ΣΔ modulator 820 as is known in the art. Also at block 1140, the outputs of the sinc filter 830 are applied to a known D/A converter 840 to generate differential digital voltage outputs that vary at the sampling rate of the input PCM stream. The resulting outputs of the D/A converter 840 form the differential digital input signal to be amplified by the integrated receive audio codec 900.

After the appropriate digital input signal is output by the PWM circuit 700 at block 1125 or the pulse code modulator circuit 800 at 1140, control proceeds to block 1145. At block 1145, either the output by the PWM circuit 700 or the output of the pulse code modulator circuit 800 is selected by the multiplexer 950 based on the configuration at block 1105. The selected signal is then amplified, for example, according to blocks 1045 through blocks 1065 of the example process 1000 discussed above. Execution of the example process 1100 then ends.

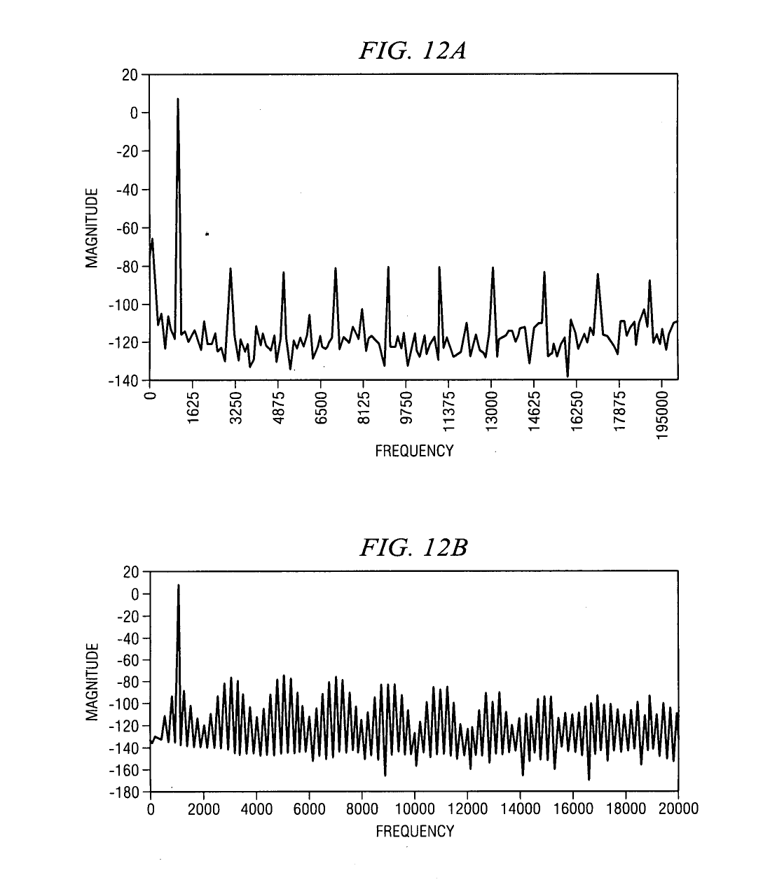

Example performance characteristics exhibited by the second example multi-mode class-D amplifier circuit 600 of FIG. 6 used to implement the example multi-mode class-D amplifier of FIG. 3 are shown in FIGS. 12A-12B. FIG. 12A illustrates an example total harmonic distortion (THD) measurement for the multi-mode class-D amplifier circuit 600 processing a digital PWM input signal having a digital carrier frequency of 1 kHz. In FIG. 12A, the output power of the multi-mode class-D amplifier circuit 600 is plotted as a function of frequency to illustrate the degree with which the harmonics of the digital carrier frequency associated with the digital PWM input signal are suppressed. FIG. 12B illustrates an example power supply rejection ratio (PSRR) measurement for the multi-mode class-D amplifier circuit 600 processing a digital PWM input signal having a digital carrier frequency of 1 kHz. In the example of FIG. 12B, a 300 mV ripple is applied to the power supply voltage driving the multi-mode class-D amplifier circuit 600. In FIG. 12B, the output power of the multi-mode class-D amplifier circuit 600 is plotted as a function of frequency to illustrate the degree with which the harmonics of the power supply and the harmonics of the digital carrier frequency associated with the digital PWM input signal are suppressed.

FIG. 13 is a block diagram of an example computer 1300 capable of implementing the apparatus and methods disclosed herein. The computer 1300 can be, for example, a server, a personal computer, a personal digital assistant (PDA), an Internet appliance, a DVD player, a CD player, a digital video recorder, a personal video recorder, a set top box, or any other type of computing device.

The system 1300 of the instant example includes a processor 1312 such as a general purpose programmable processor. The processor 1312 includes a local memory 1314, and executes coded instructions 1316 present in the local memory 1314 and/or in another memory device. The processor 1312 may execute, among other things, the example processes represented in FIGS. 10-11. The processor 1312 may be any type of processing unit, such as one or more microprocessor from the Intel® Centrino® family of microprocessors, the Intel® Pentium® family of microprocessors, the Intel® Itanium® family of microprocessors, and/or the Intel XScale® family of processors. Of course, other processors from other families are also appropriate.

The processor 1312 is in communication with a main memory including a volatile memory 1318 and a non-volatile memory 1320 via a bus 1322. The volatile memory 1318 may be implemented by Static Random Access Memory (SRAM), Synchronous Dynamic Random Access Memory (SDRAM), Dynamic Random Access Memory (DRAM), RAMBUS Dynamic Random Access Memory (RDRAM) and/or any other type of random access memory device. The non-volatile memory 1320 may be implemented by flash memory and/or any other desired type of memory device. Access to the main memory 1318, 1320 is typically controlled by a memory controller (not shown) in a conventional manner.

The computer 1300 also includes a conventional interface circuit 1324. The interface circuit 1324 may be implemented by any type of well known interface standard, such as an Ethernet interface, a universal serial bus (USB), and/or a third generation input/output (3GIO) interface.

One or more input devices 1326 are connected to the interface circuit 1324. The input device(s) 1326 permit a user to enter data and commands into the processor 1312. The input device(s) can be implemented by, for example, a keyboard, a mouse, a touchscreen, a track-pad, a trackball, an isopoint and/or a voice recognition system. For example, the one or more input devices 1326 could permit the user to perform the mode selections at blocks 1005 and/or 1025 of FIG. 10 and/or block 1105 of FIG. 11.

One or more output devices 1328 are also connected to the interface circuit 1324. The output devices 1328 can be implemented, for example, by display devices (e.g., a liquid crystal display, a cathode ray tube display (CRT)), by a printer and/or by speakers. The interface circuit 1324, thus, typically includes a graphics driver card.

The interface circuit 1324 also includes a communication device such as a modem or network interface card to facilitate exchange of data with external computers via a network (e.g., an Ethernet connection, a digital subscriber line (DSL), a telephone line, coaxial cable, a cellular telephone system, etc.).

The computer 1300 also includes one or more mass storage devices 1330 for storing software and data. Examples of such mass storage devices 1330 include floppy disk drives, hard drive disks, compact disk drives and digital versatile disk (DVD) drives.

As an alternative to implementing the methods and/or apparatus described herein in a system such as the device of FIG. 13, the methods and or apparatus described herein may be embedded in a structure such as a processor and/or an ASIC (application specific integrated circuit).

Finally, although certain example methods, apparatus and articles of manufacture have been described herein, the scope of coverage of this patent is not limited thereto. On the contrary, this patent covers all methods, apparatus and articles of manufacture fairly falling within the scope of the appended claims either literally or under the doctrine of equivalents.

What is claimed is:

1. A multi-mode class-D amplifier circuit having an analog input and a digital input, the multi-mode class-D amplifier circuit comprising:
a single-mode class-D amplifier having an amplifier input;
a smoothing filter having a filter input and a filter output, wherein the filter output is electronically coupled to the amplifier input; and
a multiplexer electronically coupled to the filter input to select between at least one of the analog input and the digital input of the multi-mode class-D amplifier circuit.

2. A multi-mode class-D amplifier circuit as defined in claim 1 wherein the single-mode class-D amplifier is configured to draw power directly from a battery power source powering the multi-mode class-D amplifier circuit.

3. A multi-mode class-D amplifier circuit as defined in claim 1 wherein the single-mode class-D amplifier comprises:
a pulse width modulation generator to generate a pulse width modulated signal; and
a power output stage configured to amplify the pulse width modulated signal.

4. A multi-mode class-D amplifier circuit as defined in claim 1 wherein the single-mode class-D amplifier comprises an integration stage coupled to the analog amplifier input and configured to implement a feedback loop based on an amplifier output of the single-mode class-D amplifier.

5. A multi-mode class-D amplifier circuit as defined in claim 1 wherein the smoothing filter comprises a two-pole low-pass filter.

6. A multi-mode class-D amplifier circuit as defined in claim 5 wherein the two-pole low-pass filter is configured to suppress a digital carrier frequency associated with the digital circuit input of the multi-mode class-D amplifier circuit.

7. A multi-mode class-D amplifier circuit as defined in claim 1 wherein the smoothing filter comprises:
a programmable gain amplifier; and
a passive network electronically coupled to the programmable gain amplifier.

8. A multi-mode class-D amplifier circuit as defined in claim 1 wherein the single-mode class-D amplifier comprises an analog ramp generator and the smoothing filter is configured to reduce at least one of a frequency mismatch or a phase mismatch between an analog ramp frequency corresponding to the analog ramp generator and a digital carrier frequency corresponding to the digital circuit input.

9. A multi-mode class-D amplifier circuit as defined in claim 1 wherein the digital input is configured to accept at least one of a natural pulse width modulated input signal, a uniform pulse width modulated input signal or pulse code modulated input symbols.

10. A multi-mode class-D amplifier circuit as defined in claim 9 wherein the single-mode class-D amplifier comprises an analog ramp generator having an analog ramp frequency asynchronous to a digital carrier frequency associated with the at least one of the natural pulse width modulated input signal, the uniform pulse width modulated input signal or the pulse code modulated input symbols.

11. An integrated audio codec comprising:
a multi-mode class-D amplifier circuit, wherein the multi-mode class-D amplifier circuit comprises:
a single-mode class-D amplifier;
a smoothing filter electronically coupled to the single-mode class-D amplifier; and
a multiplexer electronically coupled to the smoothing filter to select between at least one of an analog audio source and a digital audio source in the integrated audio codec;
an analog audio codec input to provide the analog audio source for the multi-mode class-D amplifier circuit; and
a digital audio codec input to provide the digital audio source for the multi-mode class-D amplifier circuit, wherein the digital audio codec input is configured to accept at least one of pulse code modulated symbols or a pulse width modulated signal.

12. An integrated audio codec as defined in claim 11 wherein the digital audio codec input is configured to accept pulse code modulated symbols and further comprising a sigma delta modulator to convert the pulse code modulated symbols to a multi-level output signal.

13. An integrated audio codec as defined in claim 12 further comprising:
a sinc filter to filter the multi-level output signal; and
a digital-to-analog converter to process the filtered multi-level output signal.

14. An integrated audio codec as defined in claim 11 wherein the digital audio codec input is configured to accept the pulse width modulated signal and wherein the pulse width modulated signal is generated by a pulse width modulation generator external to the integrated audio codec.

15. A method to amplify an analog signal and a digital signal, the method comprising:
selecting between at least one of the analog signal and the digital signal;
applying the selected one of the analog signal and the digital signal to a smoothing filter to generate a filtered signal; and
generating a pulse width modulated signal based on the filtered signal.

16. A method as defined in claim 15 wherein the smoothing filter comprises a two-pole low pass filter.

17. A method as defined in claim 15 wherein the smoothing filter comprises:
a programmable gain amplifier; and
a passive network electronically coupled to the programmable gain amplifier.

18. A method as defined in claim 15 wherein the digital signal corresponds to at least one of a natural pulse width modulated input signal, a uniform pulse width modulated input signal or pulse code modulated input symbols.

19. A method as defined in claim 18 wherein generating the pulse width modulated signal comprises generating an analog ramp signal having an analog ramp frequency asynchronous to a digital carrier frequency associated with the at least one of the natural pulse width modulated input signal, the uniform pulse width modulated input signal or the pulse code modulated input symbols.

20. An article of manufacture storing machine readable instructions which, when executed, cause a machine to:
select between at least one of an analog signal and a digital signal;
apply the selected one of the analog signal and the digital signal to a smoothing filter to generate a filtered signal; and
generate a pulse width modulated signal based on the filtered signal.
